(19) United States
(12) Patent Application Publication
(10) Pub. No.: US 2022/0128400 A1
(43) Pub. Date: Apr. 28, 2022

(54) LIGHT SENSOR STRUCTURE AND MANUFACTURING METHOD THEREOF

(71) Applicant: SENSORTEK TECHNOLOGY CORP., JHUBEI CITY (TW)

(72) Inventors: LI-CHIEN SU, JHUBEI CITY (TW); YEN-WEI LIAO, JHUBEI CITY (TW); YUAN-CHING HSU, JHUBEI CITY (TW)

(21) Appl. No.: 17/444,226

(22) Filed: Aug. 2, 2021

Related U.S. Application Data
(60) Provisional application No. 63/060,125, filed on Aug. 2, 2020.

(51) Int. Cl. G01J 1/42; G01J 1/04; G01J 1/02

(52) U.S. Cl. CPC G01J 1/4204; G01J 1/0295; G01J 1/0437

(57) ABSTRACT

A light sensor structure and the manufacturing method thereof are disclosed. The light sensor structure includes a substrate with a first surface and a second surface opposite to each other. A light sensing element including a light sensing area is disposed on the first surface. A reflection layer is disposed on the second surface. The reflection layer covers a portion of the second surface aligning with the light sensing area.

### FIELD OF THE INVENTION

The present application relates to a light sensor structure and the manufacturing method thereof, and particularly to a light sensor structure having a light-sensing device and the manufacturing method thereof.

### BACKGROUND OF THE INVENTION

Light sensors, such as proximity sensors and ambient light sensors, are widely applied to mobile devices, for example, mobile phones, and other consumer electronic devices. Proximity sensors can be used for detecting the distance between a user's face or another object and an electronic device. Ambient light sensors can be applied to an electronic product for sensing ambient light intensity. As shown in FIG. 1, both proximity sensors and ambient light sensors need to use a light-sensing device 91. In addition, proximity sensors generally need to use a light-emitting device 92 such as an infrared emitter or a laser emitter.

Please refer to FIG. 2, which shows a partially enlarged view of a region A of the light-sensing device 91 in FIG. 1. Generally, the light-sensing device 91 is disposed on a semiconductor substrate 93 for receiving light signals. Then the backend circuit will judge the intensity or components of the received light signals for achieving the functions of the above proximity sensors or ambient light sensors. In the trend of high screen-to-body ratio or even full screen for modem electronic devices, proximity sensors are forced to be disposed below the display, imposing stricter limitations on the size. Under this circumstance, manufacturers of light sensors have no choice but to try to shrink the overall thickness of light sensors. For example, the substrate 93 for carrying the light-sensing device 91 is ground thin to form thin light sensors.

Unfortunately, when light sensors become thinner, some of the light incident to the light-sensing device 91 will pass through the light sensors directly due to the thin substrate 93. Then, the optical sensitivity will be lowered since the effective light-sensing area on the light-sensing device 91 is reduced. Based on the above drawback, it is urged to provide a light sensor structure and a fabrication process to achieve overall miniaturization while maintaining the optical sensitivity to meet the requirements for practical applications.

### SUMMARY

An objective of the present application is to provide a light sensor structure and the manufacturing method thereof. Particularly, the light sensor structure and the manufacturing method thereof comprises a reflection layer disposed on a semiconductor substrate for reflecting the incident light passing through the light-sensing area of light-sensing devices and the substrate. Thereby, the present application can guarantee the optical sensitivity of the light sensor while shrinking the overall thickness.

The present application discloses a light sensor structure, which comprises a substrate, a light-sensing device, and a reflection layer. The substrate includes a first surface and a second surface on both sides. The light-sensing device is disposed on the first surface and includes a light-sensing area. The reflection layer is disposed on the second surface and covers the region on the second surface opposing to the light-sensing area of the light-sensing device.

The present application further discloses a manufacturing method of light sensor structure, which comprises steps of disposing a light-sensing device on a first surface of a substrate; performing backside grinding on the second surface of the substrate opposing to the first surface; and coating a reflection layer on the second surface for backside metallization such that the reflection layer covers the region on the second surface opposing to the light-sensing area of the light-sensing device.

The present application discloses another manufacturing method of light sensor structure, which comprises steps of disposing a light-sensing device on a first surface of a substrate; coating a reflection layer on a backplate; bonding the backplate to a second surface of the substrate opposing to the first surface such that the reflection layer covers the region on the second surface opposing to the light-sensing area of the light-sensing device.

### BRIEF DESCRIPTION OF THE DRAWINGS

FIG. 1 shows a cross-sectional view of the light sensor structure according to the prior art;

FIG. 2 shows a partial cross-sectional view of the light sensor structure according to the prior art;

FIG. 3 shows a partial cross-sectional view of the light sensor structure according to the first embodiment of the present application;

FIG. 4 shows a flowchart of the manufacturing method for the light sensor structure according to the first embodiment of the present application;

FIG. 5 shows the characteristics of the coating materials for the light sensor structure and the manufacturing method thereof according to the third embodiment of the present application;

FIG. 6 to FIG. 8 show packaging processes for the light sensor structure and the manufacturing method thereof according to the third embodiment of the present application; and

FIG. 9 shows a flowchart of the manufacturing method for the light sensor structure according to the third embodiment of the present application.

### DETAILED DESCRIPTION

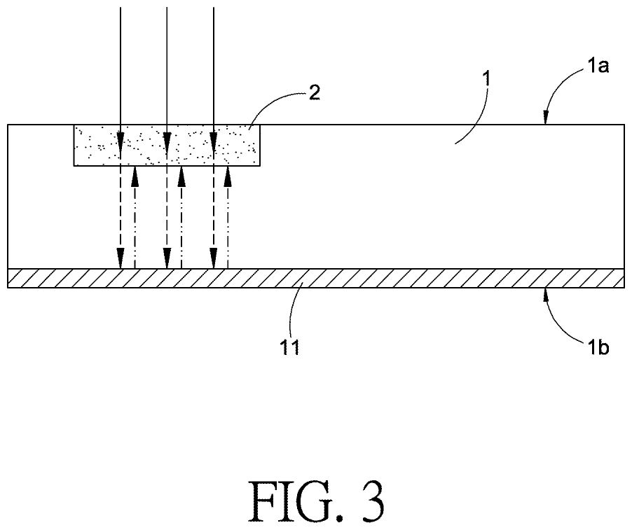

FIG. 3 shows the light sensor structure according to the first embodiment of the present application. As shown in the figure, the light sensor structure comprises a substrate 1 and a light-sensing device 2. The substrate 1 is a semiconductor substrate, for example, a silicon wafer. The light-sensing device 2 can be integrated into an application specific integrated circuit (ASIC), so that the light sensor structure includes the light-sensing device 2 and an operational circuit such as the operational circuit for proximity sensors and/or ambient light sensors. The substrate 1 includes a first surface 1a and a second surface 1b. The light-sensing device 2 is disposed on the first surface 1a. The light-sensing device 2 can be a photodiode. Thereby, a PN junction or a PIN diode can be fabricated on the first surface 1a to form the light-sensing device 2.

The substrate 1 includes a reflection layer 11 on the second surface 1b. According to the present embodiment, the reflection layer 11 can cover the whole second surface 1b of the substrate 1. Nonetheless, according to another embodiment of the present application, the reflection layer 11 can cover a portion of the second surface 1b of the substrate 1 only, for example, the region on the second surface 1b opposing to the light-sensing device 2 only. To elaborate, if the light-sensing device 2 is a photodiode, the light-sensing device 2 includes the light-sensing area formed by the PN junction or the PIN diode described above, peripheral signal processing circuits, and connection pads. Preferably, the reflection layer 11 covers at least the second surface 1b opposing to the light-sensing area of the light-sensing device 2.

The reflection layer 11 is formed by materials with good reflectivity, for example, aluminum (Al), copper (Cu), titanium (Ti), tungsten (W), gold (Au), silver (Ag), platinum (Pt), tantalum (Ta), nickel (Ni), vanadium (V), and silicon (Si). Alternatively, the oxides, alloys, or multiple layers of the above materials can be adopted.

The reflection layer 11 can be formed by coating the second surface 1b. Preferably, the backside grinding and backside metallization (BGBM) process can be adopted to form the reflection layer 11 on the second surface 1b. To elaborate, since the second surface 1b of the substrate 1 is normally the smooth back surface of a wafer, it is difficult for the coated film to form firm bonding with the substrate 1. By using the backside grinding step in the BGBM process, a surface suitable for adherence of the coated film can be formed on the second surface 1b. Then the reflection layer 11 can be formed on the second surface 1b by backside metallization. Hence, the quality and the yield of the formed reflection layer 11 can be guaranteed.

As shown in FIG. 3, in the light sensor structure according to the first embodiment of the present application, the reflection layer 11 is disposed on the second surface 1b of the substrate 1. When the light incident to the light-sensing device 2 passes through the light-sensing device 2 and the substrate 1 the light can be reflected by the reflection layer 11 and returns to the light-sensing device 2 for recycling the light and secondary light-signal sensing. Accordingly, in the light sensor structure according to the first embodiment of the present application, even if the substrate 1 for disposing the light-sensing device 2 is ground thin and shrinking the overall thickness of the light sensor, the problem of loss of light signal according to the prior art will not occur. Thereby, the optical sensitivity of the light sensor can be guaranteed.

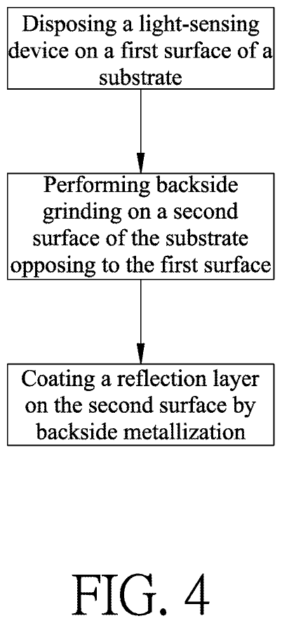

As shown in FIG. 4, the manufacturing method of the light sensor structure according to the first embodiment of the present application comprises, but not limited to, the following steps of:

Disposing a light-sensing device on a first surface of a substrate;
Performing backside grinding on a second surface of the substrate opposing to the first surface; and
Coating a reflection layer on the second surface by backside metallization.

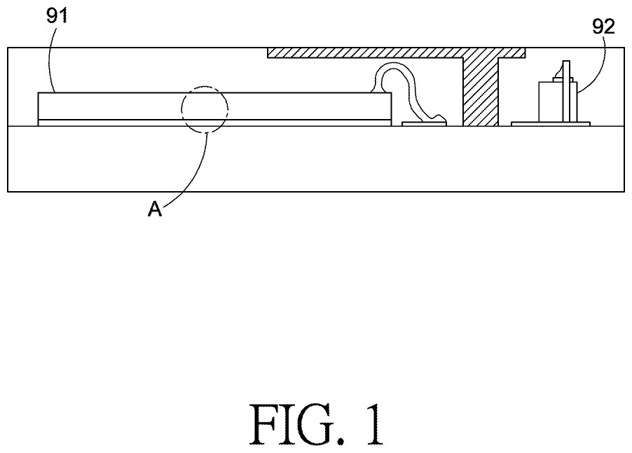

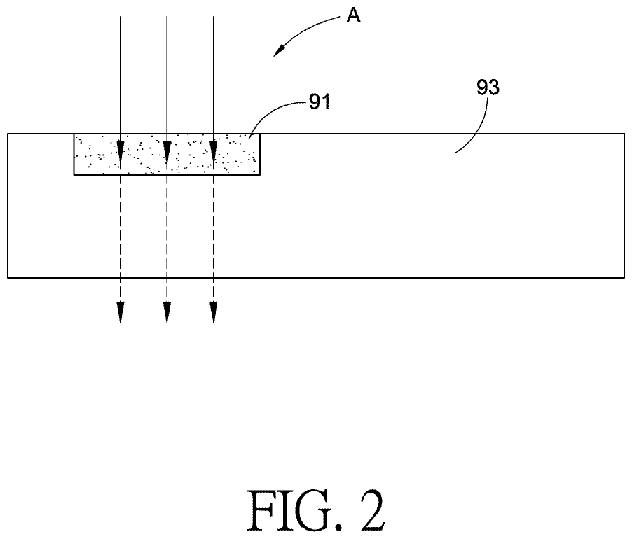

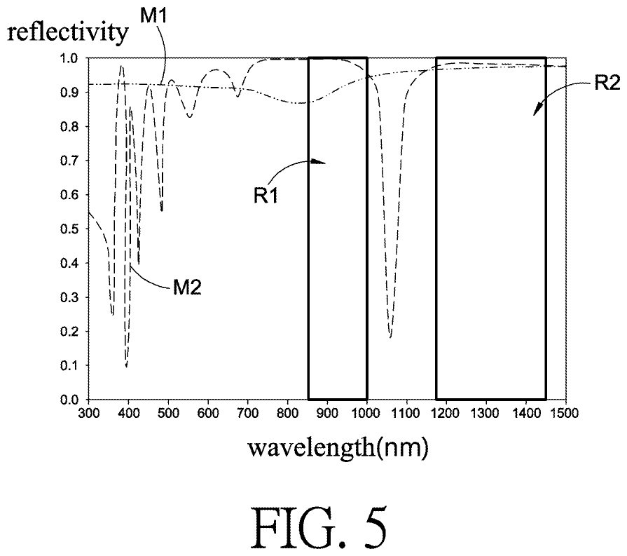

Please refer to FIG. 5. As shown in the figure, in the light sensor structure and the manufacturing method thereof according to the second embodiment of the present application, the coating material for the reflection layer 11 can be further selected. For example, when the light sensor structure is used as a proximity sensor, the light sensor structure further comprises a light-emitting device with the relative location with respect to the light-sensing device 2 as shown in FIG. 1. The operating principle of a proximity sensor is: the light-emitting device emit light, for example, infrared; the light-sensing device 2 is used for receiving the reflection light of the emitted light from the object under test; and the operational circuit of the proximity circuit estimates the distance according to the signa intensities of the emitted light and the reflection light. In general, the light-emitting device will emit infrared with wavelengths in a first wavelength range R1: 850-1000 nanometers (for example, 940 nanometers). In some specific applications, it will emit infrared with wavelengths in a first wavelength range R1: 1150-1450 nanometers (for example, 1300 nanometers).

The coating material for the reflection layer 11 can be a first coating material M1 with good reflectivity for light with wavelengths between 850 and 1450 nanometers. For example, the reflectivity is higher than 70%, and preferably higher than 90%. Thereby, no matter the wavelength of the emitted light from the light-emitting device is, the reflection layer 11 can reflect the light passing through the light-sensing device 2 and the substrate 1 effectively for ensuring the optical sensitivity of the light sensor.

Alternatively, the coating material for the reflection layer 11 can be a second coating material M2 with good reflectivity for light with wavelengths between 850 and 1450 nanometers but with low reflectivity, for example, lower than 70%, and preferably lower than 50%, for light with wavelengths between 1050 and 1100 nanometers. Thereby, if the wavelength of the light emitted from the light-emitting device is 940 nanometers, in addition to reflecting the light passing through the light-sensing device 2 and the substrate 1 effectively, the reflection layer 11 can also filter the noise with wavelengths between 1050 and 1100 nanometers. The light with wavelengths in the range between 1050 and 1100 nanometers is not originated from the emitted light. Accordingly, not only the optical sensitivity of the light sensor can be guaranteed, the signal-to-noise ratio (SNR) of the light sensor can also be increased concurrently.

As described above, the reflection layer 11 can be formed by alloys or multiple layers of materials. According to the present embodiment, the selected second coating material M2 has good reflectivity in both the first wavelength range R1: 850-1000 nanometers and the second wavelength range R2: 1150-1450 nanometers. Thereby, no mater the wavelength of the light emitted from the light-emitting device is 940 or 1300 nanometers, the light sensor will have excellent optical sensitivity and noise suppression, enabling outstanding product compatibility. Nonetheless, once costs and process complexity are considered, the coating material with good reflectivity in either the wavelength range R1 or the second wavelength range R2 can be selected, depending on users' requirements.

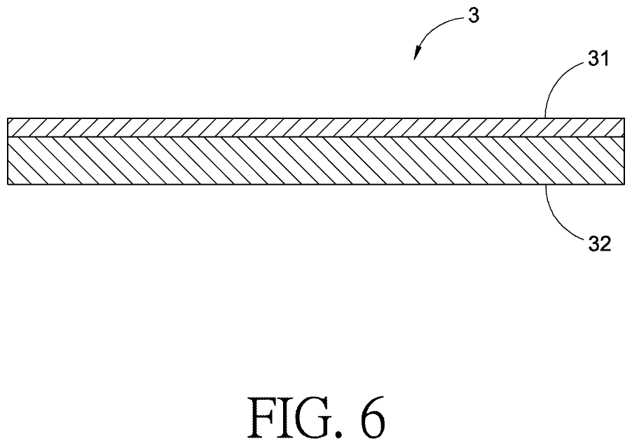

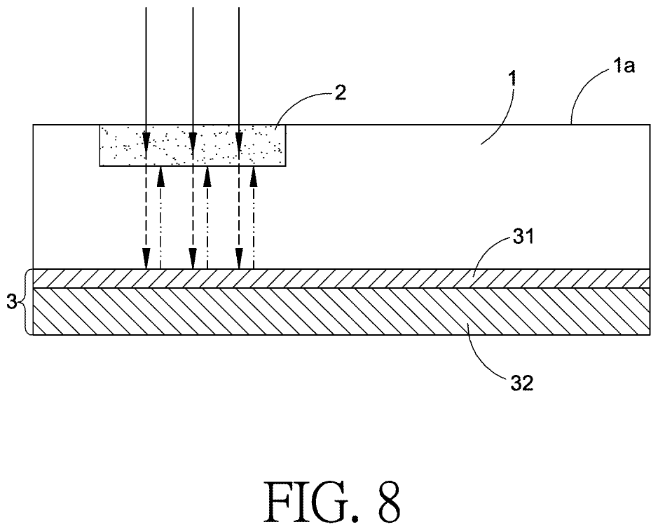

FIG. 6 to FIG. 8 show manufacturing processes for the light sensor structure according to the third embodiment of the present application. As shown in FIG. 6, a reflection layer 31 is coated on a backplate 32 for forming a reflection structure 3. Similar to the previous embodiment, the materials of the reflection layer 31 can be aluminum (Al), copper (Cu), titanium (Ti), tungsten (W), gold (Au), silver (Ag), platinum (Pt), tantalum (Ta), nickel (Ni), vanadium (V), and silicon (Si). Alternatively, the oxides, alloys, or multiple layers of the above materials can be adopted.

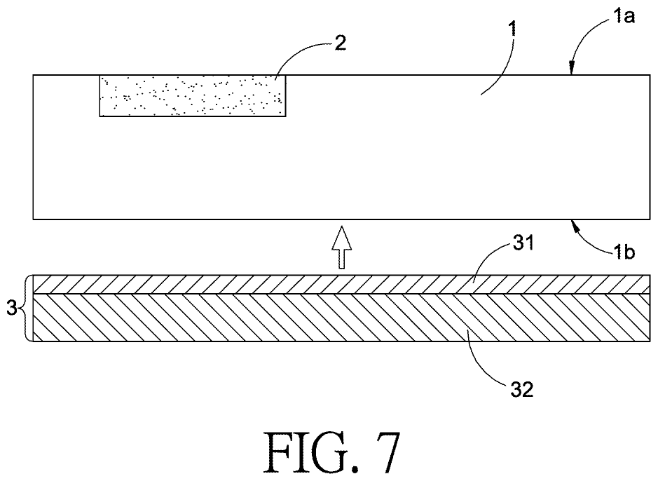

Next, as shown in FIG. 7, the backplate 32 is fixed to the second surface 1b of the substrate 1 by a bonding process for overcoming the difficulty of direct coating the smooth backside of a wafer. According to the present embodiment, the surface of the backplate 32 coated with the reflection layer 32 is bonded to the second surface 1b. Nonetheless, according to another embodiment of the present application, the surface of the backplate 32 without the reflection layer 31 instead can be bonded to the second surface 1b for reflecting the light passing through the light-sensing device 2 and the substrate 1 by using the reflection layer 31. Alternatively, according to still another embodiment of the present application, the reflection layer can be coated on both surfaces of the backplate 32. The present application is not limited to the above embodiments.

According to the third embodiment of the present application, a reflection structure 3 including a reflection layer 31 and the backplate 32 is disposed on the second surface 1b of the substrate 1. When the light incident to the light-sensing device 2 passes through the light-sensing device 2 and the substrate 1, likewise, it will be reflected to the light-sensing device 2 by the reflection layer 31 and thus effectively ensuring the optical sensitivity of the light sensor. In addition, by coating the reflection layer 31 on the backplate 32 and then bonding the backplate 32 to the second surface 1b of the substrate 1, the process complexity can be simplified.

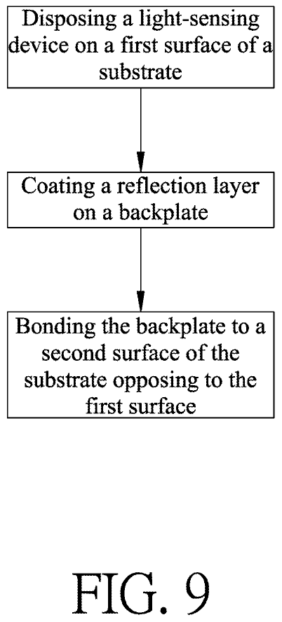

As shown in FIG. 9, the manufacturing method of the light sensor structure according to the third embodiment of the present application comprises, but not limited to, the following steps of:

Disposing a light-sensing device on a first surface of a substrate;
Coating a reflection layer on a backplate; and
Bonding the backplate to a second surface of the substrate opposing to the first surface.

To sum up, in the light sensor structure and the manufacturing method thereof according to the embodiments of the present application, a reflection layer is disposed on a semiconductor substrate for reflecting the incident light passing through the light-sensing device and the substrate to the light-sensing device. Accordingly, in the light sensor structure according to the embodiments of the present application, even if the substrate for disposing the light-sensing device is ground thin and shrinking the overall thickness of the light sensor, the optical sensitivity of the light sensor can still be guaranteed.

Moreover, according to some embodiments of the present application, the coating materials for the reflection layer can be selected to have good reflectivity in the wavelength range of the light emitted by a light-emitting device. Thereby, the reflection layer can further filter the noise with wavelengths different from the light emitted from the light-emitting device. Accordingly, in addition to ensuring the optical sensitivity of the light sensor, the signal-to-noise ratio of the light sensor can be increased concurrently.

1. A light sensor structure, comprising:
a substrate, including a first surface and a second surface on both sides respectively;
a light-sensing device, disposed on said first surface, and including a light-sensing area; and
a reflection layer, disposed on said second surface, and covering a region on said second surface opposing to said light-sensing area.

2. The light sensor structure of claim 1, wherein said reflection layer is formed on said second surface by a backside grinding and backside metallization process.

3. The light sensor structure of claim 1, wherein said reflection layer is formed on a backplate and said backplate is fixed on said second surface of said substrate.

4. The light sensor structure of claim 1, wherein a coating material for said reflection layer has reflectivity higher than 70% for the light with wavelengths between 850 and 1450 nanometers.

5. The light sensor structure of claim 1, wherein a coating material for said reflection layer has reflectivity higher than 70% for the light with wavelengths within a first wavelength range between 850 and 1450 nanometers or within a second wavelength range between 1150 and 1450 nanometers.

6. The light sensor structure of claim 5, wherein a coating material for said reflection layer has reflectivity lower than 70% for the light with wavelengths between 1050 and 1100 nanometers.

7. The light sensor structure of claim 1, and further comprising a light-emitting device, and a portion of the light emitted from said light-emitting device passing through said light-sensing device and said substrate and reflected by said reflection layer.

8. A manufacturing method of a light sensor structure, comprising steps of:
disposing a light-sensing device on a first surface of a substrate;
performing backside grinding on a second surface of said substrate opposing to said first surface;
coating a reflection layer on said second surface by backside metallization, and covering said reflection layer on a region on said second surface opposing to a light-sensing area of said light-sensing device.

9. The manufacturing method of a light sensor structure of claim 8, wherein a coating material for said reflection layer has reflectivity higher than 70% for the light with wavelengths between 850 and 1450 nanometers.

10. The manufacturing method of a light sensor structure of claim 8, wherein a coating material for said reflection layer has reflectivity higher than 70% for the light with wavelengths within a first wavelength range between 850 and 1450 nanometers or within a second wavelength range between 1150 and 1450 nanometers.

11. The manufacturing method of a light sensor structure of claim 10, wherein a coating material for said reflection layer has reflectivity lower than 70% for the light with wavelengths between 1050 and 1100 nanometers.

12. A manufacturing method of a light sensor structure, comprising steps of:
disposing a light-sensing device on a first surface of a substrate;
coating a reflection layer on a backplate; and
bonding said backplate to a second surface of said substrate opposing to said first surface, and covering said reflection layer on a region on said second surface opposing to a light-sensing area of said light-sensing device.

13. The manufacturing method of a light sensor structure of claim 12, wherein a coating material for said reflection layer has reflectivity higher than 70% for the light with wavelengths between 850 and 1450 nanometers.

14. The manufacturing method of a light sensor structure of claim 12, wherein a coating material for said reflection layer has reflectivity higher than 70% for the light with wavelengths within a first wavelength range between 850 and 1450 nanometers or within a second wavelength range between 1150 and 1450 nanometers.

15. The manufacturing method of a light sensor structure of claim 14, wherein a coating material for said reflection layer has reflectivity lower than 70% for the light with wavelengths between 1050 and 1100 nanometers.
